(19) United States
(12) Patent Application Publication
(10) Pub. No.: US 2025/0155797 A1
(43) Pub. Date: May 15, 2025

(54) GENERATE 3D PHOTORESIST PROFILES USING DIGITAL LITHOGRAPHY

(71) Applicant: Applied Materials, Inc., Santa Clara, CA (US)

(72) Inventors: Chi-Ming TSAI, San Jose, CA (US); Thomas L. LAIDIG, Richmond, CA (US)

(21) Appl. No.: 18/715,317

(22) PCT Filed: Dec. 16, 2021
(86) PCT No.: PCT/US2021/063803

§ 371 Date: May 31, 2024

(51) Int. Cl. G03F 7/00; G03F 7/16

(52) U.S. Cl. CPC G03F 7/0037; G03F 7/168; G03F 7/70291; G03F 7/70358

(57) ABSTRACT

Embodiments described herein provide for a system, a software application, and a method of a lithography process to form a three-dimensional profile in a single exposure operation. An image projections system of a lithography system will provide a plurality of shots to a photoresist layer. To form a three-dimensional profile in the photoresist layer, a local shot density of a plurality of shots within an exposure area will be varied. The local shot density will determine a dose provided by the image projection system at each sub-grid of an exposure area. The dose will determine the thickness of a photoresist layer when the plurality of shots are projected to the photoresist layer.

### BACKGROUND

### Field

Embodiments of the present disclosure generally relate to lithography systems. More particularly, embodiments of the present disclosure relate to a system, a software application, and a method of a lithography process to form a three-dimensional profile in a single exposure operation.

### Description of the Related Art

Photolithography is widely used in the manufacturing of semiconductor devices, such as for back-end processing of semiconductor devices, and display devices, such as liquid crystal displays (LCDs). For example, large area substrates are often utilized in the manufacture of LCDs. LCDs, or flat panel displays, are commonly used for active matrix displays, such as computers, touch panel devices, personal digital assistants (PDAs), cell phones, television monitors, and the like. Generally, flat panel displays include a layer of liquid crystal material as a phase change material at each pixel, sandwiched between two plates. When power from a power supply is applied across or through the liquid crystal material, an amount of light passing through the liquid crystal material is controlled, i.e., selectively modulated, at the pixel locations enabling images to be generated on the display.

One challenge with lithography is forming three-dimensional profiles with smooth transitions across the profile. Existing lithography systems lack a desired ability to form the three-dimensional profiles in a single exposure operation.

Accordingly, what is needed in the art is a system, a software application, and/or a method of a lithography process with an improved ability to form three-dimensional profiles with a single exposure.

### SUMMARY

In one embodiment, a system is provided. The system includes a slab and a moveable stage disposable over the slab. The moveable stage is configured to support a substrate having a photoresist layer disposed thereon. The system further includes a controller configured to provide mask pattern data to a lithography system. The mask pattern data includes an exposure area with a gray pattern and the gray pattern is defined by a plurality of sub-grids. Each sub-grid includes a pattern area defined therein. The system further includes a lithography system support coupled to the slab having an opening to allow the moveable stage to pass thereunder. The lithography system has a processing unit with a plurality of image projection systems that receive the mask pattern data and each image projection system includes a spatial light modulator with a plurality of spatial light modulator pixels to project a plurality of shots. The controller is configured to position a plurality of pattern areas within each of the sub-grids to vary a local shot density at each sub-grid and the controller is configured to instruct each of the spatial light modulators to project the plurality of shots to the plurality of pattern areas in each sub-grid of the gray pattern.

In another embodiment, a non-transitory computer-readable medium is provided. The non-transitory computer-readable medium is storing instructions that, when executed by a processor, cause a computer system to perform the steps of providing a mask pattern data having a plurality of exposure areas to a processing unit of a lithography system. The processing unit includes a plurality of image projection systems that receive the mask pattern data and each exposure area includes a gray pattern. The gray pattern includes a plurality of sub-grids; and a plurality of pattern areas in each sub-grid. The plurality of pattern areas correspond to a local shot density of each sub-grid. In a single scan of a substrate having a photoresist layer disposed thereon under the plurality of image projection systems, the steps further include projecting a plurality of shots to the plurality of pattern areas of the gray pattern to the photoresist layer and developing the photoresist layer to form a three-dimensional profile in the photoresist layer. The three-dimensional profile is defined by the local shot density at each sub-grid of each exposure area.

In yet another embodiment, a method is provided. The method includes providing a mask pattern data having a plurality of exposure areas to a processing unit of a lithography system. The processing unit includes a plurality of image projection systems that receive the mask pattern data and each exposure area includes a gray pattern. The gray pattern includes a plurality of sub-grids and a plurality of pattern areas in each sub-grid. The plurality of pattern areas correspond to a local shot density of each sub-grid. In a single scan of a substrate having a photoresist layer disposed thereon under the plurality of image projection systems, the method further includes projecting a plurality of shots to the plurality of pattern areas of the gray pattern to the photoresist layer and developing the photoresist layer to form a three-dimensional profile in the photoresist layer. The three-dimensional profile is defined by the local shot density at each sub-grid of each exposure area.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a perspective view of a system according to one embodiment.

FIG. 2A is a schematic, cross-sectional view of an image projection system according to one embodiment.

FIG. 2B and FIG. 2C are schematic views of a spatial light modulator according to one embodiment.

FIG. 3 is a schematic view of a computing system according to one embodiment.

FIG. 4 is a schematic view of the single exposure lithography application according to one embodiment.

FIG. 5 is a schematic view of a controller according to one embodiment.

FIG. 6 is a schematic, plan view of a portion of a substrate during a digital lithography process according to one embodiment.

FIG. 7A is a schematic, plan view of an exposure area divided into a plurality of sub-grids according to one embodiment.

FIG. 7B is a schematic, plan view of a gray pattern with a plurality of sub-grids according to one embodiment.

FIG. 8A is a diagram of a local shot density of a gray pattern according to one embodiment.

FIG. 8B is a chart corresponding to the diagram of FIG. 8A according to one embodiment.

FIG. 9 is a flow diagram of a method of forming a three-dimensional profile in a photoresist layer with a lithography process according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to a system, a software application, and a method of a lithography process to form a three-dimensional profile in a single exposure operation. One embodiment of the system includes a controller configured to provide mask pattern data to a lithography system. The mask pattern data includes a gray pattern. The lithography system has a processing unit with a plurality of image projection systems that receive the mask pattern data. Each image projection system includes a spatial light modulator with a plurality of spatial light modulator pixels to project a multiplicity of shots. The controller is configured to vary the local shot density across the substrate.

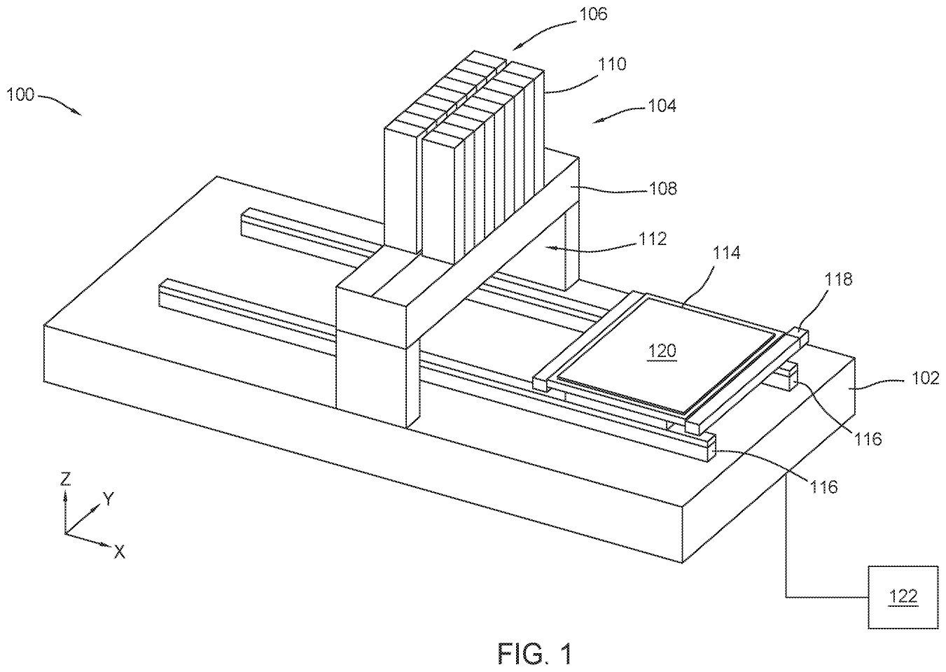

FIG. 1 is a perspective view of a system 100, such as a digital lithography system, that may benefit from embodiments described herein. The system 100 includes a stage 114 and a processing apparatus 104. The stage 114 is supported by a pair of tracks 116 disposed on a slab 102. A substrate 120 is supported by the stage 114. The stage 114 is supported by a pair of tracks 116 disposed on the slab 102. The stage 114 moves along the pair of tracks 116 in the X direction as indicated by the coordinate system shown in FIG. 1. In one embodiment, which can be combined with other embodiments described herein, the pair of tracks 116 is a pair of parallel magnetic channels. As shown, each track of the pair of tracks 116 extends in a straight line path. An encoder 118 is coupled to the stage 114 in order to provide information of the location of the stage 114 to a controller 122.

The controller 122 is generally designed to facilitate the control and automation of the processing techniques described herein. The controller 122 may be coupled to or in communication with the processing apparatus 104, the stage 114, and the encoder 118. The processing apparatus 104 and the encoder 118 may provide information to the controller 122 regarding the substrate processing and the substrate aligning. For example, the processing apparatus 104 may provide information to the controller 122 to alert the controller 122 that substrate processing has been completed. The controller 122 facilitates the control and automation of methods of a lithography process that includes varying the local shot density during a single exposure. A program (or computer instructions), which may be referred to as an imaging program, readable by the controller 122, determines which tasks are performable on a substrate 120. The program includes a mask pattern data and code to monitor and control the processing time and substrate position. The mask pattern data corresponds to a pattern to be written into the photoresist using the electromagnetic radiation.

The substrate 120 comprises any suitable material, for example, glass, which is used as part of a flat panel display. In other embodiments, which can be combined with other embodiments described herein, the substrate 120 is made of other materials capable of being used as a part of the flat panel display. The substrate 120 has a film layer to be patterned formed thereon, such as by pattern etching thereof, and a photoresist layer formed on the film layer to be patterned, which is sensitive to electromagnetic radiation, for example ultra-violet (UV) or deep UV “light”. A positive photoresist includes portions of the photoresist, when exposed to radiation, are respectively soluble to a photoresist developer applied to the photoresist after the pattern is written into the photoresist using the electromagnetic radiation. A negative photoresist includes portions of the photoresist, when exposed to radiation, will be respectively insoluble to photoresist developer applied to the photoresist after the pattern is written into the photoresist using the electromagnetic radiation. The chemical composition of the photoresist determines whether the photoresist is a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. After exposure of the photoresist to the electromagnetic radiation, the resist is developed to leave a patterned photoresist on the underlying film layer. Then, using the patterned photoresist, the underlying thin film is transfer etched to form a similar pattern in the underlying film layer. The underlying film layer is utilized to form a portion of the electronic circuitry of the display panel.

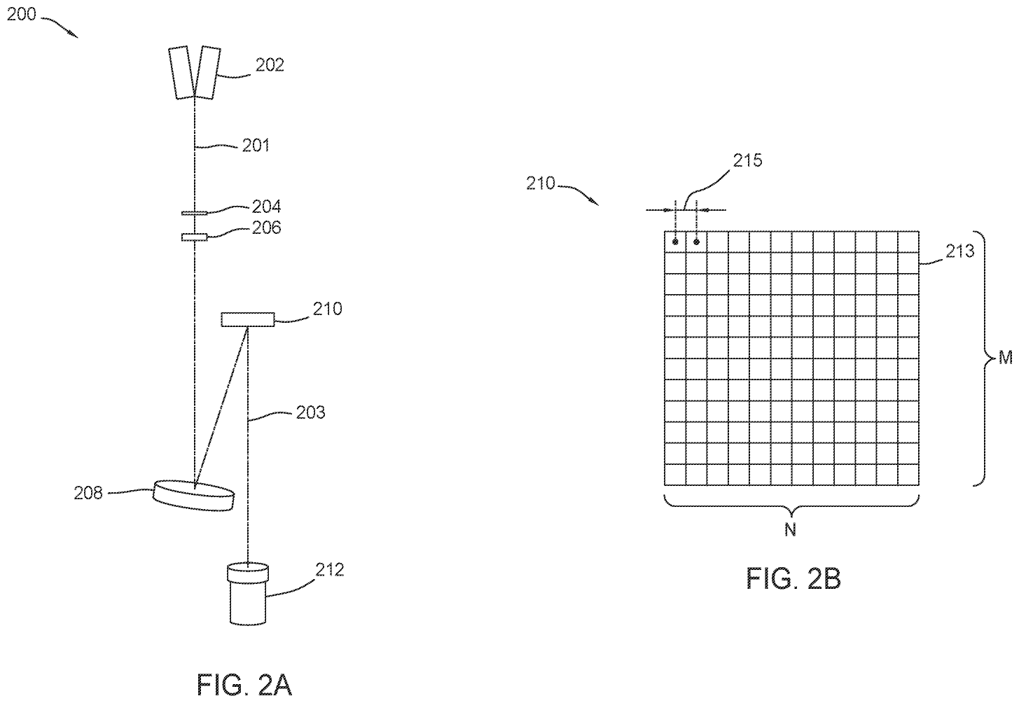

The processing apparatus 104 includes a support 108 and a processing unit 106. The processing apparatus 104 straddles the pair of tracks 116 and is disposed on the slab 102, and thereby includes an opening 112 for the pair of tracks 116 and the stage 114 to pass under the processing unit 106. The processing unit 106 is supported over the slab 102 by a support 108. In one embodiment, which can be combined with other embodiments described herein, the processing unit 106 is a pattern generator configured to expose a photoresist in a photolithography process. In some embodiments, which can be combined with other embodiments described herein, the pattern generator is configured to perform a maskless lithography process. The processing unit 106 includes a plurality of image projection systems. One example of an image projection system is show in FIG. 2A. In one embodiment, which can be combined with other embodiments described herein, the processing unit 106 contains as many as 84 image projection systems. Each image projection system is disposed in a case 110. The processing unit 106 is useful to perform maskless direct pattern writing to a photoresist or other electromagnetic radiation sensitive materials.

FIG. 2A is a schematic, cross-sectional view of an image projection system 200 that may be used in system 100. The image projection system 200 includes a spatial light modulator 210 and projection optics 212. The components of the image projection system 200 vary depending on the spatial light modulator 210 being used. The spatial light modulator 210 includes an array of electrically addressable elements. The electrically addressable elements include, but are not limited to, digital micromirrors, liquid crystal displays (LCDs), liquid crystal over silicon (LCoS) devices, ferroelectric liquid crystal on silicon (FLCoS) devices, and microshutters. The spatial light modulator 210 includes a plurality of spatial light modulator pixels. Each spatial light modulator pixel of the plurality of spatial light modulator pixels are individually controllable and are configured to project a write beam corresponding to a pixel of a plurality of pixels. The compilation of plurality of pixels form of the pattern written into the photoresist, referred to herein as the mask pattern. The projection optics 212 includes projection lenses, for example 10× objective lenses, used to project the light onto the substrate 120. In operation, based on the mask pattern data provided to the spatial light modulator 210 by the controller 122, each spatial light modular pixel of the plurality of spatial light modulator pixels is at an “on” position or “off” position. Each spatial light modular pixel at an “on” position forms a write beam that the projection optics 212 then projects the write beam to the photoresist layer surface of the substrate 120 to form a pixel of the mask pattern.

In one embodiment, which can be combined with other embodiments described herein, the spatial light modulator 210 is a DMD. The image projection system 200 includes a light source 202, an aperture 204, a lens 206, a frustrated prism assembly 208, the DMD, and the projection optics 212. The DMD includes a plurality of mirrors, i.e, the plurality of spatial light modulator pixels. Each mirror of the plurality of mirrors corresponds to a pixel that may correspond to a pixel of the mask pattern. In some embodiments, which can be combined with other embodiments described herein, the DMD includes more than about 4,000,000 mirrors. The light source 202 is any suitable light source, such as a light emitting diode (LED) or a laser, capable of producing a light having a predetermined wavelength. In one embodiment, which can be combined with other embodiments described herein, the predetermined wavelength is in the blue or near ultraviolet (UV) range, such as less than about 450 nm. The frustrated prism assembly 208 includes a plurality of reflective surfaces. In operation, a light beam 201 is produced by the light source 202. The light beam 201 is reflected to the DMD by the frustrated prism assembly 208. When the light beam 201 reaches the mirrors of the DMD, each mirror at an “on” position reflect the light beam 201, i.e., forms a write beam, also known as a “shot”, that the projection optics 212 then projects as a shot to the photoresist layer surface of the substrate 120. The plurality of write beams 203, also known as a plurality of shots, forms a plurality of pixels of the mask pattern.

FIG. 2B is a schematic view of the spatial light modulator 210 that is a DMD. The plurality of mirrors 213, also known as the plurality of spatial light modulator pixels, are arranged in a grid having M rows and N columns. Each of the plurality of mirrors 213 is operable to be in an “on” position or an “off” position. A pixel pitch 215 is defined as the distance between the centroid of adjacent spatial light modulator pixels.

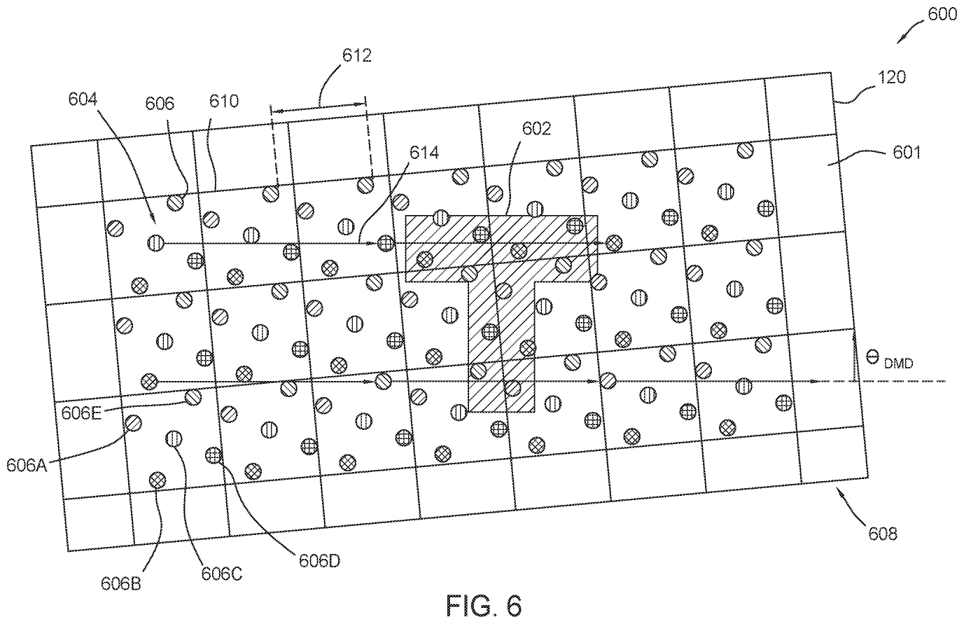

The plurality of spatial light modulator pixels of the spatial light modulator 210 are configured in an aggregated shot pattern 604 (shown in FIG. 6) where each spatial light modulator pixel corresponds to a potential shot 606 (shown in FIG. 6). Each potential shot 606 represents the centroid of a mirror 213. The controller 122 (shown in FIG. 1) provides instructions to the spatial light modulator 210 based on the mask pattern data. The mask pattern data determines which of the plurality of mirrors 213 are in the “on” position. In embodiments when a mirror 213 is in the “on” position, a shot is delivered. In embodiments when a mirror 213 is in the “off” position, a shot is not delivered.

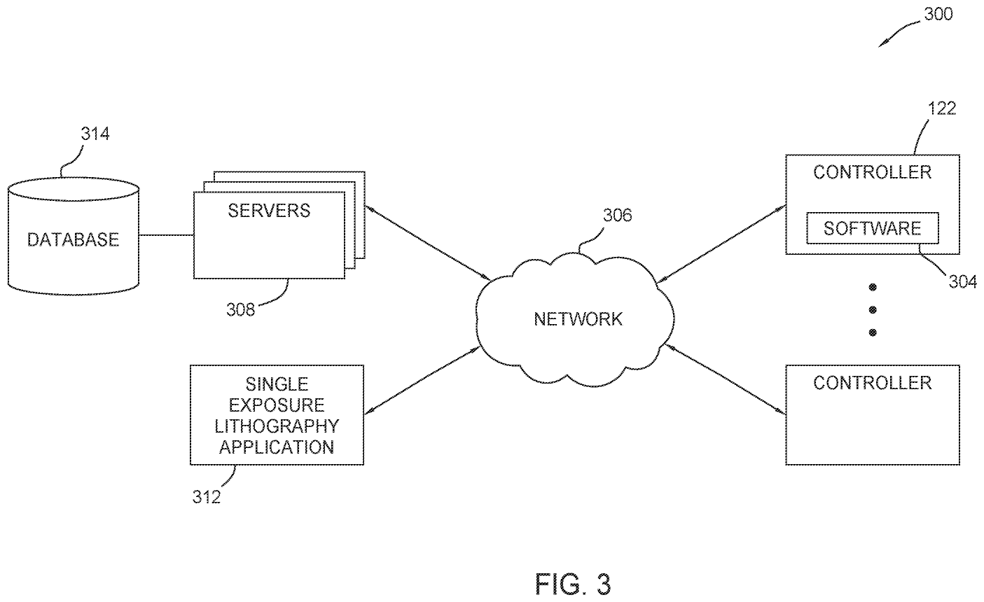

FIG. 3 is a schematic view of a computing system 300 configured for varying a local shot density across a substrate in which embodiments of the disclosure may be practiced. As shown in FIG. 3, the computing system 300 may include a plurality of servers 308, a single exposure lithography application 312, and a plurality of controllers 122 (i.e., computers, personal computers, mobile/wireless devices, only two of which are shown for clarity), each connected to a communications network 306 (for example, the Internet). The servers 308 may communicate with the database 314 via a local connection (for example, a Storage Area Network (SAN) or Network Attached Storage (NAS)) or over the Internet. The servers 308 are configured to either directly access data included in the database 314 or to interface with a database manager that is configured to manage data included within the database 314.

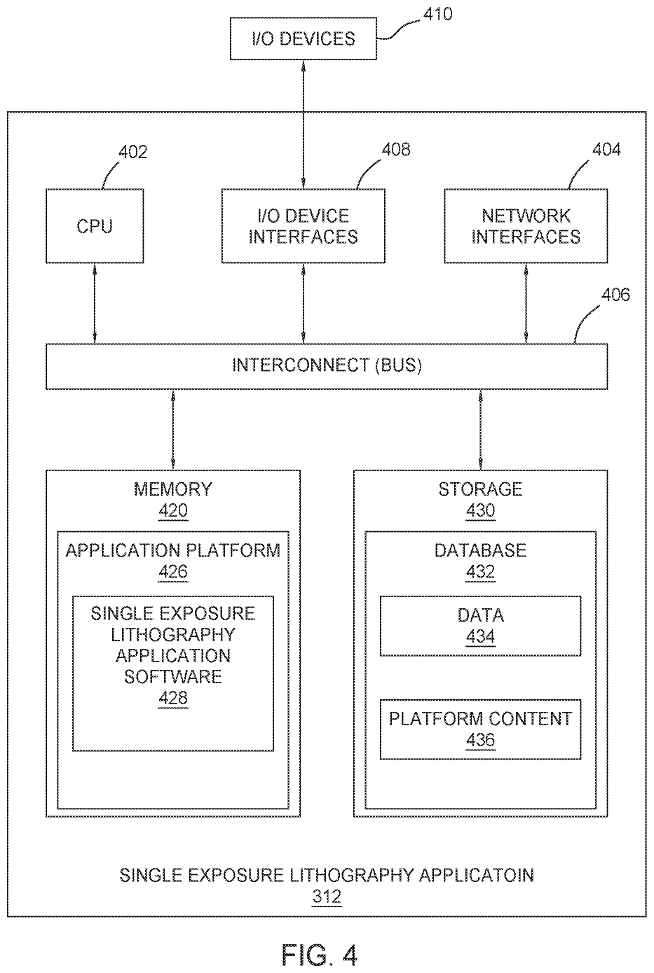

Each controller 122 may include components of a computing device, for example, a processor, system memory, a hard disk drive, a battery, input devices such as a mouse and a keyboard, and/or output devices such as a monitor or graphical user interface, and/or a combination input/output device such as a touchscreen which not only receives input but also displays output. Each server 308 and the single exposure lithography application 312 may include a processor and a system memory (not shown), and may be configured to manage content stored in database 314 using, for example, relational database software and/or a file system. The I/O device interfaces 408, as shown in FIG. 4, may be programmed to communicate with one another, the controllers 122, and the single exposure lithography application 312 using a network protocol such as, for example, the TCP/IP protocol. The single exposure lithography application 312 may communicate directly with the controllers 122 through the communications network 306. The controllers 122 are programmed to execute software 304, such as programs and/or other software applications, and access applications managed by servers 308.

In the embodiments described below, users may respectively operate the controllers 122 that may be connected to the servers 308 over the communications network 306. Pages, images, data, documents, and the like may be displayed to a user via the controllers 122. Information and images may be displayed through a display device and/or a graphical user interface in communication with the controller 122.

It is noted that the controller 122 may be a personal computer, laptop mobile computing device, smart phone, video game console, home digital media player, network-connected television, set top box, and/or other computing devices having components suitable for communicating with the communications network 306 and/or the required applications or software. The controller 122 may also execute other software applications configured to receive content and information from the single exposure lithography application 312.

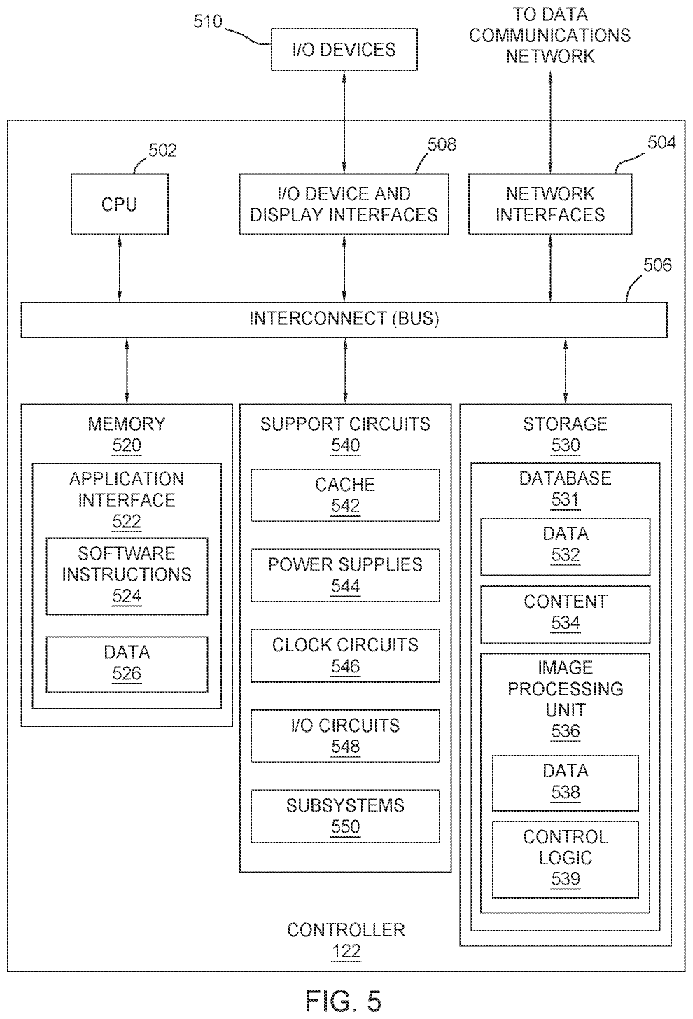

FIG. 4 is a schematic view of the single exposure lithography application 312. The single exposure lithography application 312 includes, without limitation, a central processing unit (CPU) 402, a network interface 404, memory 420, and storage 430 communicating via an interconnect 406. The single exposure lithography application 312 may also include I/O device interfaces 408 connecting I/O devices 410 (for example, keyboard, video, mouse, audio, touchscreen, etc.). The single exposure lithography application 312 may further include the network interface 504 (shown in FIG. 5) configured to transmit data via the data communications network.

The CPU 402 retrieves and executes programming instructions stored in the memory 420 and generally controls and coordinates operations of other system components. Similarly, the CPU 402 stores and retrieves application data residing in the memory 420. The CPU 402 is included to be representative of a single CPU, multiple CPU's, a single CPU having multiple processing cores, and the like. The interconnect 406 is used to transmit programming instructions and application data between the CPU 402, I/O device interfaces 408, storage 430, network interfaces 404, and memory 420.

The memory 420 is generally included to be representative of a random access memory and, in operation, stores software applications and data for use by the CPU 402. Although shown as a single unit, the storage 430 may be a combination of fixed and/or removable storage devices, such as fixed disk drives, floppy disk drives, hard disk drives, flash memory storage drives, tape drives, removable memory cards, CD-ROM, DVD-ROM, Blu-Ray, HD-DVD, optical storage, network attached storage (NAS), cloud storage, or a storage area-network (SAN) configured to store non-volatile data.

The memory 420 may store instructions and logic for executing an application platform 426 which may include single exposure lithography application software 428. The storage 430 may include a database 432 configured to store data 434 and associated application platform content 436. The database 432 may be any type of storage device.

Network computers are another type of computer system that can be used in conjunction with the disclosures provided herein. Network computers do not usually include a hard disk or other mass storage, and the executable programs are loaded from a network connection into the memory 420 for execution by the CPU 502 (shown in FIG. 5). A typical computer system will usually include at least a processor, memory, and an interconnect coupling the memory to the processor.

FIG. 5 is a schematic view of a controller 122 used to access the single exposure lithography application 312 and retrieve or display data associated with the application platform 426. The controller 122 may include, without limitation, a central processing unit (CPU) 502, a network interface 504, an interconnect 506, a memory 520, storage 530, and support circuits 540. The controller 122 may also include an I/O device interface 508 connecting I/O devices 510 (for example, keyboard, display, touchscreen, and mouse devices) to the controller 122.

Like CPU 402, CPU 502 is included to be representative of a single CPU, multiple CPU's, a single CPU having multiple processing cores, etc., and the memory 520 is generally included to be representative of a random access memory. The interconnect 506 may be used to transmit programming instructions and application data between the CPU 502, I/O device interfaces 508, storage 530, network interface 504, and memory 520. The network interface 504 may be configured to transmit data via the communications network 306, for example, to transfer content from the single exposure lithography application 312. Storage 430, such as a hard disk drive or solid-state storage drive (SSD), may store non-volatile data. The storage 530 may contain a database 531. The database 531 may contain data 532, other content 534, and an image process unit 536 having data 538 and control logic 539. Illustratively, the memory 520 may include an application interface 522, which itself may display software instructions 524, and/or store or display data 526. The application interface 522 may provide one or more software applications which allow the controller to access data and other content hosted by the single exposure lithography application 312.

As shown in FIG. 1, the system 100 includes the controller 122. The controller 122 includes a central processing unit (CPU) 502, memory 520, and support circuits 540 (or 1/O 508). The CPU 502 may be one of any form of computer processors that are used in industrial settings for controlling various processes and hardware (e.g., pattern generators, motors, and other hardware) and monitor the processes (e.g., processing time and substrate position). The memory 520, as shown in FIG. 5, is connected to the CPU 502, and may be one or more of a readily available memory, such as random access memory (RAM), read only memory (ROM), floppy disk, hard disk, or any other form of digital storage, local or remote. Software instructions and data can be coded and stored within the memory for instructing the CPU 502. The support circuits 540 are also connected to the CPU 502 for supporting the processor in a conventional manner. The support circuits 540 may include conventional cache 542, power supplies 544, clock circuits 546, input/output circuitry 548, subsystems 550, and the like. A program (or computer instructions) readable by the controller 122 determines which tasks are performable on a substrate 120. The program may be software readable by the controller 122 and may include code to monitor and control, for example, the processing time and substrate position.

It should be borne in mind, however, that all of these and similar terms are to be associated with the appropriate physical quantities and are merely convenient labels applied to these quantities. Unless specifically stated otherwise as apparent from the following discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission, or display devices.

The present example also relates to an apparatus for performing the operations herein. This apparatus may be specially constructed for the required purposes, or it may comprise a general purpose computer selectively activated or reconfigured by a computer program stored in the computer. Such a computer program may be stored in a computer readable storage medium, such as, but is not limited to, read-only memories (ROMs), random access memories (RAMs), EPROMs, EEPROMs, flash memory, magnetic or optical cards, any type of disk including floppy disks, optical disks, CD-ROMs, and magnetic-optical disks, or any type of media suitable for storing electronic instructions, and each coupled to a computer system interconnect.

The algorithms and displays presented herein are not inherently related to any particular computer or other apparatus. Various general purpose systems may be used with programs in accordance with the teachings herein, or it may prove convenient to construct a more specialized apparatus to perform the required method operations. The structure for a variety of these systems will appear from the description above. In addition, the present examples are not described with reference to any particular programming language, and various examples may thus be implemented using a variety of programming languages.

As described in greater detail within, embodiments of the disclosure relate to a lithography application relating to the ability to apply mask pattern data to a substrate 120 in a single exposure lithography process. The embodiments described herein relate to a software application platform. The software application platform includes methods of forming three-dimensional profiles in a single exposure.

FIG. 6 is a schematic, plan view of a portion 600 of the substrate 120 during a digital lithography process. The substrate 120 includes a photoresist layer 601 disposed over the substrate 120. In some embodiments, which can be combined with other embodiments described herein, an underlying film layer is disposed under the photoresist layer. An image projection system 200 (shown in FIG. 2) corresponding to the portion 600 of the substrate 120 receives the mask pattern data from the controller 122. The mask pattern data defines one or more exposure areas 602 overlaid on the substrate 120. The exposure areas 602 define an area of the photoresist layer 601 to be exposed to write beams from the image projection system 200. The exposure area 602 includes, but is not limited to, a circular, triangular, elliptical, regular polygonal, irregular polygonal, and/or irregular shape. One or more exposure areas 602 may be provided in the mask pattern data.

The plurality of spatial light modulator pixels of the spatial light modulator 210 are configured in an aggregated shot pattern 604. The aggregated shot pattern 604 is overlaid on the substrate 120. Each spatial light modulator pixel of the spatial light modulator 210 corresponds to a potential shot 606. The aggregated shot pattern 604 depicts the locations where each of the potential shots 606 could be projected on the substrate 120. The mask pattern data determines which of the plurality of spatial light modulator pixels is in an “off” position or an “on” position. Each potential shot 606 represents the centroid of a mirror 213 (shown in FIG. 2B). When the spatial light modulator pixel is in the “on” position, the potential shot 606 is projected to the corresponding location on the substrate 120.

As shown in FIG. 6, a grid 608 of a plurality of unit areas 610 is overlaid on the substrate 120. Each unit area 610 corresponds to one spatial light modulator pixel of the spatial light modulator 210. In the embodiment shown in FIG. 6, each unit area 610 is operable to receive five distinct potential shots 606 (i.e., a first shot 606A, a second shot 606B, a third shot 606C, a fourth shot 606D, and a fifth shot 606E) depending on the mask pattern data. Each unit area 610 may include hundreds of shots 606, such as between 50 and 500 potential shots. For example, each unit area 610 includes between 60 and 150 potential shots 606. Increasing the number of potential shots 606 will allow for finer control of light concentration on the photoresist layer 601. Each of the first shot 606A, the second shot 606B, the third shot 606C, the fourth shot 606D, and the fifth shot 606E across the plurality of spatial light modulator pixels are projected sequentially.

The aggregated shot pattern 604 has an aggregated shot pitch 612. The aggregated shot pitch 612 is the distance between adjacent potential shots 606. The aggregated shot pitch 612 is determined by the pixel pitch 215 (shown in FIG. 2B) and the magnification of the image projection system 200. Each plurality of potential shots 606 has a shot step 614 between each potential shot 606. The plurality of potential shots 606 are uniformly distributed within each unit area 610 to minimize the distance between each of the potential shots 606. The spatial light modulator 210 is slightly rotated against the shot step 614 direction by θ_{DMD}. The image projection system(s) 200 can be installed on the support 108 such that the spatial light modulators 210 are rotated by θ_{DMD}.

When the substrate 120 scans under the image projection system 200, the processing unit 106 projects the plurality of shots 606 corresponding to the plurality of spatial light modulator pixels in the “on” position to the portion 600 of the substrate 120. Each shot 606 of the plurality of shots 606 is projected inside the exposure area 602, as defined according to the mask pattern data. The plurality of shots 606 in the exposure area 602 may partially overlap. For example, when the plurality of shots 606 are sufficiently dense within the exposure area 602, a pattern corresponding to the exposure area 602 is exposed in the photoresist layer 601.

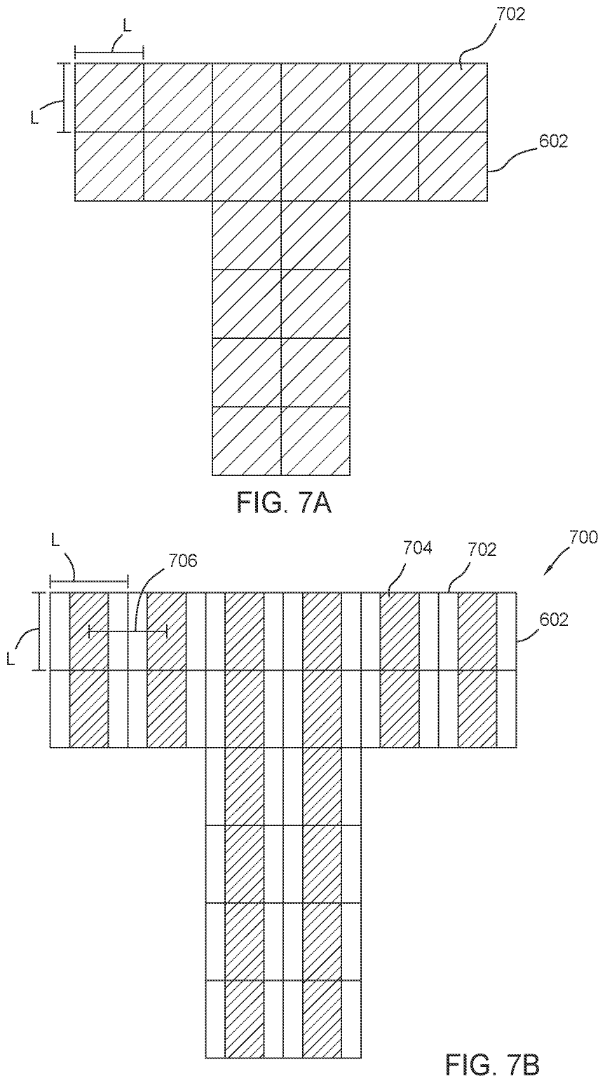

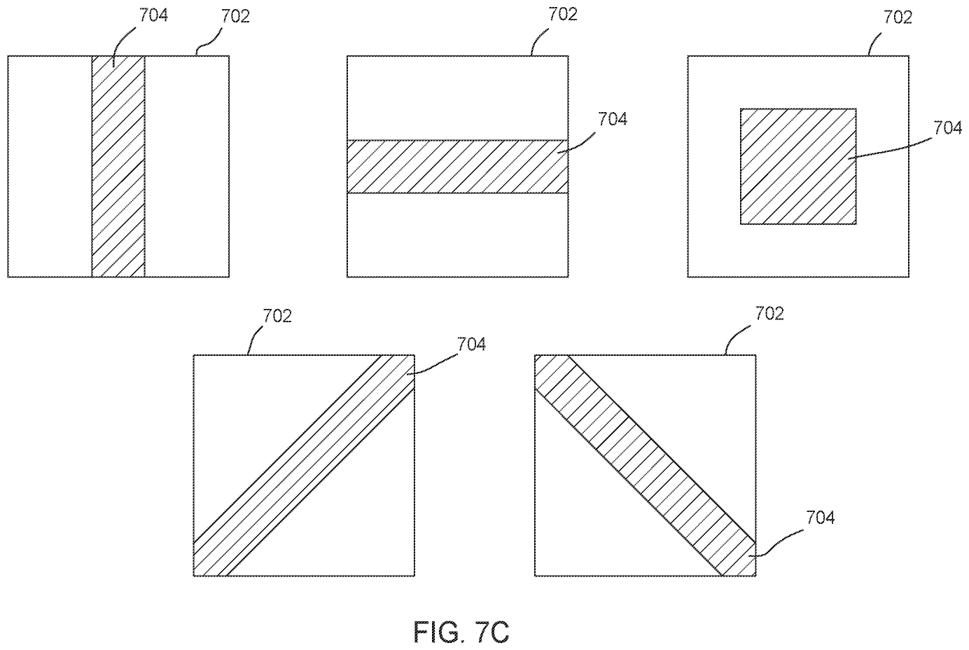

FIG. 7A is a schematic, plan view of an exposure area 602 divided into a plurality of sub-grids 702. Each sub-grid 702 has a length L. The gray pattern 700 is provided in the mask pattern data by the controller 122. The gray pattern 700 is determined according to the method 900 described herein. In some embodiments, which can be combined with other embodiments described herein, the area of the sub-grid 702 is less than the area of the plurality of mirrors 213 (shown in FIG. 2B). The length L is less than the optical resolution of the image projection system 200. The optical resolution is less than a pixel pitch 215. Additionally, the length L may be reduced to accommodate a three-dimensional profile with steep slopes. Reducing the length L will provide for the steep slope in the three-dimensional profile to be formed as more sub-grids 702 will make up the exposure area 602.

FIG. 7B is a schematic, plan view of a gray pattern 700 with a plurality of sub-grids 702. The sub-grids 702 are utilized to vary the local shot density of an exposure area 602. As the plurality of shots 606 (shown in FIG. 6) corresponding to the plurality of spatial light modulator pixels in the “on” positon are provided to the exposure area 602, a gray pattern 700 may be formed to vary a local shot density within each sub-grid 702. A plurality of pattern areas 704 are defined within each sub-grid by the mask pattern data. The plurality of pattern areas 704 may be determined according to the single exposure lithography application 312, described herein.

The plurality of pattern areas 704 are defined to achieve the local shot density. For example, in order to reduce the local shot density in each sub-grid 702 by 50%, the plurality of pattern areas 704 within each sub-grid 702 are formed with an area that is 50% of the sub-grid 702. The pattern areas 704 are 50% of the area of the sub-grid 702 and achieve a local shot density of 50%. In such an example, only “shots” which fall into the pattern areas 704 will be provided in order to achieve the desired dose during processing. The ratio of the pattern areas 704 to the area of each of the sub-grids 702 defines a gray pattern density map. The gray pattern density map is utilized to define a shape and size of the plurality of pattern areas 704.

A pattern area pitch 706 is defined as the distance between a centroid of adjacent pattern areas 704. In some embodiments, which can be combined with other embodiments described herein, the length L and a pattern area pitch 706 are aligned to improve the resolution of the three-dimensional profile to be formed.

In one embodiment, which can be combined with other embodiments described herein, each sub-grid 702 includes the same local shot density. In another embodiment, which can be combined with other embodiments described herein, the local shot density is different in at least two adjacent sub-grids 702. The potential shots 606 (shown in FIG. 6) corresponding to the plurality of spatial light modulator pixels overlapping with the pattern areas 704 of the gray pattern 700 are in the “on” position, as instructed by the controller 122 according to the mask pattern data. As such, the number of the plurality of shots 606 i.e., the local shot density, aligns with the ratio of an area of the plurality of pattern areas 704 to the area of the sub-grid 702. In some embodiments, the local shot density in each sub-grid 702 may not perfectly align with the ratio of an area of the plurality of pattern areas 704 to the area of the sub-grid 702 due to the discrete nature of digital lithography.

FIG. 7C is a schematic, plan view of a plurality of pattern areas 704. FIG. 7C shows examples of the pattern areas 704 in each sub-grid 702. The plurality of pattern areas 704 are not limited to those shown in FIG. 7C. The shape of the pattern areas 704 include, but is not limited to, a circular, triangular, elliptical, regular polygonal, irregular polygonal, and/or irregular shape. The shape of the pattern areas 704 are determined based on complexity of the exposure area 602 and imperfections from the image projection system 200. For example, the shape of the pattern areas 704 may be determined to avoid shapes that induce optical aberrations by the image projection system 200. Each shape of the pattern area 704 may be disposed at a rotation angle within the sub-grid 702. Each pattern area 704 may achieve a local shot density of between 0% and 100% in each sub-grid 702.

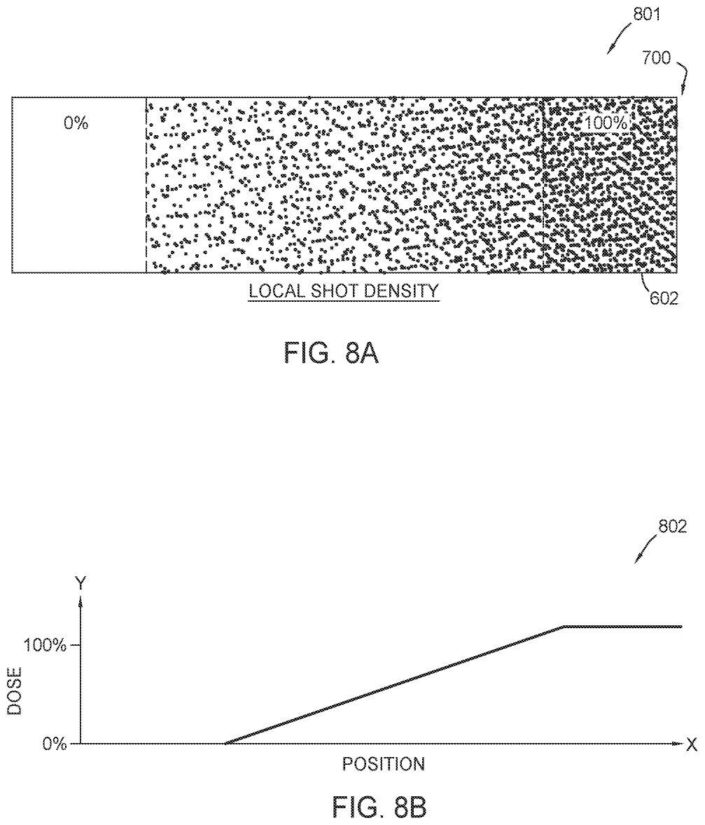

FIG. 8A is a diagram 801 of local shot density of a gray pattern 700. The local shot density varies from 0% to 100% across an exposure area 602. The local shot density is determined by the ratio of the plurality of pattern areas 704 within the sub-grids 702 to the area of the sub-grid 702 of the gray pattern 700. FIG. 8B is a chart 802 corresponding to the diagram 801 of FIG. 8A. The X-axis corresponds to a positon along the exposure area 602 shown in FIG. 8A. The Y-axis corresponds to a dose applied to the exposure area 602. The dose corresponds to a percentage of the photoresist layer 601 that is developed and removed due to exposing the photoresist to the intensity of light emitted from the light source 202.

In embodiments where the local shot density is 0% (i.e., the plurality of mirrors 213 are all in the “off” position), the dose is 0% and thus the thickness of the photoresist layer 601 remaining would be 100%. In embodiments where the local shot density is 100% (i.e., the plurality of mirrors 213 are all in the “on” position), the dose is 100% and thus the photoresist layer 601 would be completely removed. Therefore, varying the local shot density across the exposure area 602 by defining the pattern areas 704 will allow for a three-dimensional profile to be formed in the photoresist layer 601.

For example, varying the local shot density as shown in FIG. 8A will form a ramp profile in the photoresist layer 601 (shown in FIG. 6). The three-dimensional profile in the photoresist layer 601 can be transferred into one or more underlying layers by an etch process (e.g., an anisotropic etch process), which can incorporate the three-dimensional profile in an integrated circuit, display, etc. The three-dimensional profile may be a curved, spherical, aspherical, concave, convex, tapered, half-cylindrical, or angled profile.

The three-dimensional profile may be formed in a single exposure operation of the image projection system 200. Executing the exposure operation in a single pass can reduce the occurrence of multiple exposures. The single exposure operation leads to increases in throughput and reduces alignment issues. Further, regardless of the queue time (the time between the exposure and development of the photoresist layer 601), the profile will be formed due to only requiring a single exposure. Thus, the gray pattern 700 allows for improved throughput, ability to develop three-dimensional profiles in the photoresist layer 601, and reduces overlay issues associate with the usage of multiple masks.

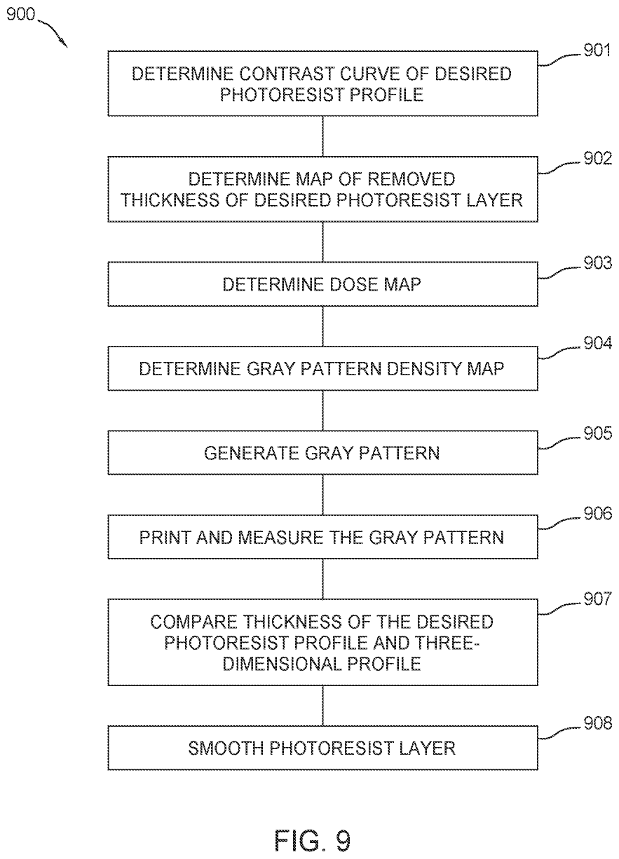

FIG. 9 is a flow diagram of a method 900 of forming a three-dimensional profile in a photoresist layer 601 with a lithography process. The method 900 allows for defining a gray pattern 700 according to a desired photoresist profile to be formed. A controller 122 as described herein facilitates the operations of the method 900. The method 900 is performed in a single exposure operation of the image projection system 200. Prior to the method 900, a desired photoresist profile is determined. The desired photoresist profile may be a three-dimensional profile. The method 900 may be at least partially executed by the single exposure lithography application 312.

At operation 901, a contrast curve of the desired photoresist profile is determined. The contrast curve tracks a dose versus a removed thickness of a photoresist layer with the desired photoresist profile. Such a curve may be empirically determined beforehand, and applicable for future operations. At operation 902, a map of the removed thickness across the desired photoresist profile is determined. The map depicts the removed thickness of the photoresist at each position. The map of the removed thickness is determined based on the contrast curve. At operation 903, a dose map is determined. The dose map is determined by referencing the map of the removed thickness against the contract curve. The dose corresponds to a percentage of the photoresist layer 601 that is developed from exposing the photoresist to the intensity of light emitted from a light source 202 of the image projection system 200. For example, by determining the removed thickness at each location, the necessary dose can be determined at each location.

At operation 904, a gray pattern density map is determined. The gray pattern density map is derived by determining a ratio of the local dose at each location (i.e., at each sub-grid 702) to a nominal dose. The gray pattern density map determines the number of shots 606 that need to be projected per sub-grid 702 to generate the dose based on the dose map. The gray pattern density map determines a local shot density at each sub-grid 702. At operation 905, a gray pattern 700 is generated based on the gray pattern density map. The gray pattern density map dictates the ratio of the local does to the nominal dose. A plurality of pattern areas 704 in each sub-grid 702 define the gray pattern 700. The shape and size of the plurality of pattern areas 704 are determined at operation 905 to correspond with the gray pattern density map. The gray pattern 700 is provided to the image projection system 200 by the controller 122 in the form of mask pattern data.

At operation 906, the gray pattern is printed and measured. When the substrate 120 scans under the image projection system 200 in a single pass the processing unit 106 projects a plurality of shots 606 according to the gray pattern 700. The local shot density is varied across the plurality of sub-grids 702. As the dose at each sub-grid 702 depends on the local shot density, the thickness of photoresist layer 601 removed will vary across the substrate 120. Therefore, the photoresist layer 601 will have a three-dimensional profile. The thickness of the three-dimensional profile may then be measured. At operation 907, the thickness of the desired photoresist profile is compared with the thickness of the three-dimensional profile formed in the photoresist layer 601 at the operation 906. In embodiments where the thicknesses do not match, the dose map is adjusted accordingly. For example, the dose at each location can be increased or decreased. As a result, the pattern areas 704 will increase or decrease in area responsively. Operations 903-907 may then be repeated until the thickness of the desired photoresist profile is equal with the thickness of the three-dimensional profile.

At operation 908, the photoresist layer 601 is smoothed. In some embodiments, the number of shots 606 projected in each sub-grid 702 of the gray pattern 700 will not always lead to a smooth thickness transition between adjacent sub-grids 702 of the photoresist layer 601. Therefore, one of a first smoothing operation, a second smoothing operation, or a third smoothing operation may be performed to improve the transition of thickness in the photoresist layer 601.

The first smoothing operation includes widening the laser pulse of the light source 202 projected to the substrate 120. As the stage 114 (shown in FIG. 1) moves at a constant speed during a scan, widening the laser pulse (i.e., increasing the pulse width) will reduce the roughness of the photoresist layer 601 in the direction of movement of the stage 114. Conventionally, the pulse width of the light source 202 multiplied by the speed of the stage 114 is about 40% or less of a pixel pitch 215 (shown in FIG. 2B). However, in the first smoothing operation, the pulse width of the light source 202 multiplied by the speed of the stage 114 is about 100% to about 150% of the pixel pitch 215 to allow for blending of the plurality of shots 606 that have been projected. The blending occurs in the direction of movement of the stage 114.

The second smoothing operation includes tuning the image projection system(s) 200 to print the gray pattern 700 slightly out of focus. Therefore, the plurality of shots 606 projected in the exposure area 602 will be blurred. The plurality of shots 606 being blurred will increase the blending of the adjacent shots 606. Therefore, when the photoresist layer 601 is developed, the thickness transitions will be smoother.

The third smoothing operation includes a baking process. The baking process may be performed on photoresist layer 601 after exposure (i.e., the operation 906). The baking process may be performed on an underlying film layer after development of the photoresist layer 601. The baking temperature is about 150° C. to about 250° C. The baking has a diffusion effect, which allows the photoresist or the underlying film layer to slightly melt. Thus, the photoresist or the underlying film will be smoothed.

In summation, a system, a software application, and a method of a lithography process to form a three-dimensional profile in a single exposure operation is provided herein. To form a three-dimensional profile in a photoresist layer, a local shot density of a plurality of shots within an exposure area will vary. The local shot density will determine a dose provided by an image projection system at each sub-grid of an exposure area. The dose will determine the thickness of a photoresist layer when the plurality of shots are projected to the photoresist layer. By adjusting the local shot density by defining a plurality of pattern areas where the plurality of shots are to be projected within each sub-grid of the exposure area, the thickness of the photoresist layer can be formed with a three-dimensional profile. The three-dimensional profile may be formed in a single exposure operation of the lithography system. Utilizing the gray pattern allows for improved throughput, ability to develop three-dimensional profiles in the photoresist layer, and reduces overlay issues associate with the usage of multiple masks.

While the foregoing is directed to embodiments of the present disclosure, other and further embodiments of the disclosure may be devised without departing from the basic scope thereof, and the scope thereof is determined by the claims that follow.

What is claimed is:

1. A system, comprising:
a slab;
a moveable stage disposable over the slab, the moveable stage configured to support a substrate having a photoresist layer disposed thereon;
a controller configured to provide mask pattern data to a lithography system, the mask pattern data having an exposure area with a gray pattern, wherein the gray pattern is defined by a plurality of sub-grids, each sub-grid including a pattern area defined therein; and
a lithography system support coupled to the slab having an opening to allow the moveable stage to pass thereunder, wherein:
the lithography system has a processing unit with a plurality of image projection systems that receive the mask pattern data;
each image projection system comprising a spatial light modulator with a plurality of spatial light modulator pixels to project a plurality of shots;
the controller is configured to position a plurality of pattern areas within each of the sub-grids to vary a local shot density at each sub-grid; and
the controller is configured to instruct each of the spatial light modulators to project the plurality of shots to the plurality of pattern areas in each sub-grid of the gray pattern.

2. The system of claim 1, wherein the local shot density corresponds to a ratio of area of the pattern area to each sub-grid.

3. The system of claim 2, wherein the controller is configured to increase the local shot density to increase a thickness of the photoresist layer to be removed during development.

4. The system of claim 3, wherein the controller is configured to decrease the local shot density to decrease a thickness of the photoresist layer to be removed during development.

5. The system of claim 1, wherein the controller is configured to instruct the plurality of shots to be projected to the plurality of pattern areas, wherein the plurality of shots exposes the photoresist layer to an intensity of light emitted from the image projection systems to form a three-dimensional profile in the photoresist layer.

6. The system of claim 5, wherein the three-dimensional profile is curved, spherical, aspherical, concave, convex, tapered, half-cylindrical, or angled profile.

7. The system of claim 1, wherein each spatial light modulator pixel of the plurality of spatial light modulator pixels of the spatial light modulator is individually controllable by the controller.

8. The system of claim 1, wherein the local shot density defined by each pattern area in one sub-grid is different than the local shot density in at least one adjacent sub-grid.

9. A non-transitory computer-readable medium storing instructions that, when executed by a processor, cause a computer system to perform the steps of:
providing a mask pattern data having a plurality of exposure areas to a processing unit of a lithography system, the processing unit having a plurality of image projection systems that receive the mask pattern data, wherein each exposure area includes a gray pattern, the gray pattern comprising:
a plurality of sub-grids; and
a plurality of pattern areas in each sub-grid, the plurality of pattern areas corresponding to a local shot density of each sub-grid; and
in a single scan of a substrate having a photoresist layer disposed thereon under the plurality of image projection systems:
projecting a plurality of shots to the plurality of pattern areas of the gray pattern to the photoresist layer; and
developing the photoresist layer to form a three-dimensional profile in the photoresist layer, the three-dimensional profile defined by the local shot density at each sub-grid of each exposure area.

10. The non-transitory computer-readable medium of claim 9, wherein each image projection system comprises a spatial light modulator with a plurality of mirrors to project the plurality of shots to the exposure area of an aggregated shot pattern.

11. The non-transitory computer-readable medium of claim 9, wherein a pulse width of a light source in each image projection system multiplied by a speed of the single scan of the substrate is about 100% to 150% of a pixel pitch, wherein the pixel pitch is a distance between adjacent centroids of spatial light modulator pixels in the plurality of image projection systems.

12. The non-transitory computer-readable medium of claim 9, wherein the plurality of image projection systems are out of focus, wherein the plurality of shots are blurred in the exposure areas.

13. The non-transitory computer-readable medium of claim 9, further comprising a baking process, wherein the photoresist layer is baked at a temperature of about 150° C. to about 250° C.

14. A method, comprising:
providing a mask pattern data having a plurality of exposure areas to a processing unit of a lithography system, the processing unit having a plurality of image projection systems that receive the mask pattern data, wherein each exposure area includes a gray pattern, the gray pattern comprising:
a plurality of sub-grids; and
a plurality of pattern areas in each sub-grid, the plurality of pattern areas corresponding to a local shot density of each sub-grid; and
in a single scan of a substrate having a photoresist layer disposed thereon under the plurality of image projection systems:
projecting a plurality of shots to the plurality of pattern areas of the gray pattern to the photoresist layer; and
developing the photoresist layer to form a three-dimensional profile in the photoresist layer, the three-dimensional profile defined by the local shot density at each sub-grid of each exposure area.

15. The method of claim 14, wherein each image projection system comprises a spatial light modulator with a plurality of mirrors to project the plurality of shots to the exposure area of an aggregated shot pattern.

16. The method of claim 14, wherein a pulse width of a light source in each image projection system multiplied by a speed of the single scan of the substrate is about 100% to 150% of a pixel pitch, wherein the pixel pitch is a distance between adjacent centroids of spatial light modulator pixels in the plurality of image projection systems.

17. The method of claim 14, wherein the plurality of image projection systems are out of focus, wherein the plurality of shots are blurred in the exposure areas.

18. The method of claim 14, further comprising a baking process, wherein the photoresist layer is baked at a temperature of about 150° C. to about 250° C.

19. The method of claim 14, wherein the plurality of pattern areas of the gray pattern are derived based on the local shot density desired at each sub-grid.

20. The method of claim 14, further comprising performing an etch process on the photoresist layer such that the three-dimensional profile can be transferred into one or more underlying film layers disposed under the photoresist layer.
